(19) United States
(12) Patent Application Publication
(10) Pub. No.: US 2016/0174418 A1
(43) Pub. Date: Jun. 16, 2016

(54) PCM COOLING

(71) Applicant: INTERNATIONAL BUSINESS MACHINES CORPORATION, Armonk, NY (US)

(72) Inventors: YONG LIN HE, Shanghai (CN); XUE FENG WANG, Shanghai (CN)

(21) Appl. No.: 14/906,300

(22) PCT Filed: Oct. 22, 2014
(86) PCT No.: PCT/CN2014/089160

§ 371 Date: Jan. 20, 2016

(30) Foreign Application Priority Data
Nov. 29, 2013 (CN) 201310629107.8

(51) Int. Cl. H05K 7/20; F28D 15/02; F28D 20/02; F28D 7/00

(52) U.S. Cl. CPC H05K 7/20836; H05K 7/20827; H05K 7/20745; F28D 7/0008; F28D 15/0275; F28D 20/021

(57) ABSTRACT

Temperature and threshold parameters relating to the cooling system are received. A control condition suitable for the cooling system is determined. If the ambient temperature is lower than the first temperature threshold, the working fluid passage between the free cooling device and the system to be cooled and the working fluid passage between the free cooling device and the PCM cooling device are turned on, in addition to the PCM cooling device is set into the first working mode. If the ambient temperature, AT, is higher than the second temperature threshold and the temperature of the PCM material is lower than the melted state temperature threshold, the working fluid passage between the PCM cooling device and the system to be cooled is turned on, the working fluid passages relating to the free cooling device is turned off, and the PCM cooling device is set into the second working mode.

### BACKGROUND OF THE INVENTION

The present invention relates to cooling device, and more particularly, to phase change material (PCM) cooling device, cooling system comprising the PCM cooling device, and method for controlling the cooling system.

With the rapid development of information technology (IT) technology, various data centers of large scale have been constructed to satisfy the demand of storing and processing data. While providing higher storage capacity and more rapid processing speed, data centers consume more and more energy. For example, in the year of 2006, the electricity used by data centers in US is about 1.5% of total national power generation. Of the energy consumed by data centers, the consumption of cooling system makes up a significant proportion, sometimes up to 50% or more. According to the statistics of recent years, with the scale expansion of data centers, the energy consumption doubles every 5 years, which not only increases the operating cost, but also worsens the working condition of servers, bringing the problems of hot spots and equipment failure.

The cooling system in a data center may utilize many kinds of cooling devices proposed in the heating, ventilation, and air conditioning (HVAC) industry. The most typical and conventional one is the compression-type cooling device using a compressor and a condenser, such as an air conditioner. The conventional compression-type cooling devices have relatively high energy consumption. In the case of an appropriate outside temperature, free cooling devices can be used in cooling a data center. The free cooling devices make cooling by using outdoor air under certain temperature conditions, and complement the conventional compression-type cooling devices well. The utilization of the free cooling devices may reduce the energy consumption of the data center. The cooling process of the free cooling devices can be divided into two categories (i.e., direct cooling and indirect cooling). Direct cooling process introduces outdoor low temperature air directly into the data center to cool IT equipment, having high cooling efficiency. At the same time, however, during this process, the contaminated, polluted outdoor air might be introduced into the data center and potentially harm the IT equipment. The indirect cooling process does not introduce outdoor air directly into the data center, but uses air-air or air-water heat-exchanger to cool IT equipment. Because of the temperature difference inside the heat-exchanger, the indirect cooling process has lower cooling efficiency than the direct cooling, but is safer.

It can be understood that, the free cooling devices have very low energy consumption; in most areas, however, they are not widely used due to the limitations of external conditions. Therefore, even though having free cooling devices as a complement, the existing data center cooling system still has relatively high energy consumption. What is desired is an improved solution, which makes better use of the cooling capacity of the free cooling process, thereby reducing the energy consumption of the cooling system.

### SUMMARY

In view of the disadvantages in the prior art, the present invention proposes a solution, which jointly uses a PCM cooling device and a free cooling device to reduce the energy consumption of a cooling system.

Embodiments of the present invention disclose a system for controlling a cooling system. According to a first aspect, the present invention provides a cooling device that includes: a cooling tank with one or more sidewalls; a tube filled with Phase Change Material (PCM) material, arranged in the cooling tank; an inlet module, configured to introduce working fluid from a free cooling device in a first working mode, and to introduce working fluid from a system to be cooled in a second working mode; a distribution system used to distribute the working fluid introduced from the inlet module, bringing it in contact with the tube; and an outlet module, configured to discharge the working fluid having contacted with the tube into the free cooling device in the first working mode, and to discharge the working fluid having contacted with the tube into the system to be cooled in the second working mode.

According to a second aspect, the present invention provides a cooling system that includes: a free cooling device for providing cooled working fluid in a predetermined temperature condition; a working fluid passage connecting the free cooling device and a PCM cooling device in parallel with a system to be cooled; a working fluid passage connecting a fluid outlet of the free cooling device with an inlet module of the PCM cooling device; a working fluid passage connecting a fluid inlet of the free cooling device with an outlet module of the PCM cooling device; and passage control components for controlling a plurality of working fluid passages by turning on and turning off the plurality of working fluid passages.

According to a third aspect, the present invention provides a method for controlling a cooling system where: temperature parameters and threshold parameters relating to a PCM cooling device are received, wherein the temperature parameters comprise ambient temperature, AT, and a temperature, Tₚ, of a PCM material in the PCM cooling device, and the threshold parameters comprise: a first temperature threshold, T₁, representing an ambient temperature required for solidification of the PCM material in the PCM cooling device; a second temperature threshold, T₂, representing an ambient temperature required for proper functioning of a free cooling device; a solidified state temperature threshold, Tₛ₁, indicating that the PCM material is in a solid state; and a melted state temperature threshold, Tₛ₂, indicating that the PCM material is in a liquid state; the temperature parameters are compared with the threshold parameters to determine a control condition suitable for the PCM cooling device; responsive to determining that the ambient temperature, AT, is lower than the first temperature threshold, T₁, a working fluid passage between the free cooling device and the system to be cooled is turned on, a working fluid passage between the free cooling device and the PCM cooling device is turned on, and the PCM cooling device is set into a first working mode; and responsive to determining that the ambient temperature, AT, is higher than the second temperature threshold, T₂, and the temperature, Tₚ, of the PCM material is lower than the melted state temperature threshold, Tₛ₂, a working fluid passage between the PCM cooling device and a system to be cooled is turned on, a working fluid passages relating to the free cooling device is turned off, and the PCM cooling device is set into a second working mode.

By using the solution according to the embodiments of the invention, the PCM cooling device and the free cooling device are used in combination, thereby making better use of the cooling capacity of the free cooling process, and reducing the energy consumption of the cooling system.

### BRIEF DESCRIPTION OF THE DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1 shows a schematic diagram of a PCM cooling device according to one example;

FIG. 2 shows properties of some candidate inorganic compounds;

FIG. 3 shows a schematic diagram of the inner structure of the cooling tank according to one example;

FIG. 4 shows a schematic diagram of the PCM cooling device functioning in the first working mode;

FIG. 5 shows a schematic diagram of the PCM cooling device functioning in the second working mode;

FIG. 6 shows a schematic diagram of a cooling system according to one example;

FIG. 7 shows a flow chart of a method for controlling the cooling system according to one example;

FIG. 8 shows a flow chart of a method for controlling the cooling system according to another example; and

FIG. 9 shows a structural block diagram of a controlling module according to one example.

### DETAILED DESCRIPTION

Some preferable embodiments will be described in more detail with reference to the accompanying drawings, in which the preferable embodiments of the present disclosure have been illustrated. However, the present disclosure can be implemented in various manners, and thus should not be construed to be limited to the embodiments disclosed herein. On the contrary, those embodiments are provided for the thorough and complete understanding of the present disclosure, and completely conveying the scope of the present disclosure to those skilled in the art.

In the embodiments of the invention, a PCM cooling device is provided, which can be connected via fluid passages to one of a free cooling device and a system to be cooled. This allows the PCM cooling device to be able to store “cold energy” by using the free cooling device under an appropriate outside condition, and when necessary, provide the stored cold energy to the system to be cooled and thus get it cooled. Therefore, by using the PCM cooling device as an intermediary for storing cold energy, we may make better use of the cooling capacity of the free cooling device and realize the reduction of energy consumption. Correspondingly, the invention further provides a cooling system comprising the above PCM cooling device and a free cooling device, and a method for controlling the cooling system, such that the PCM cooling device can be switched among different working modes, thereby storing and releasing cold energy effectively.

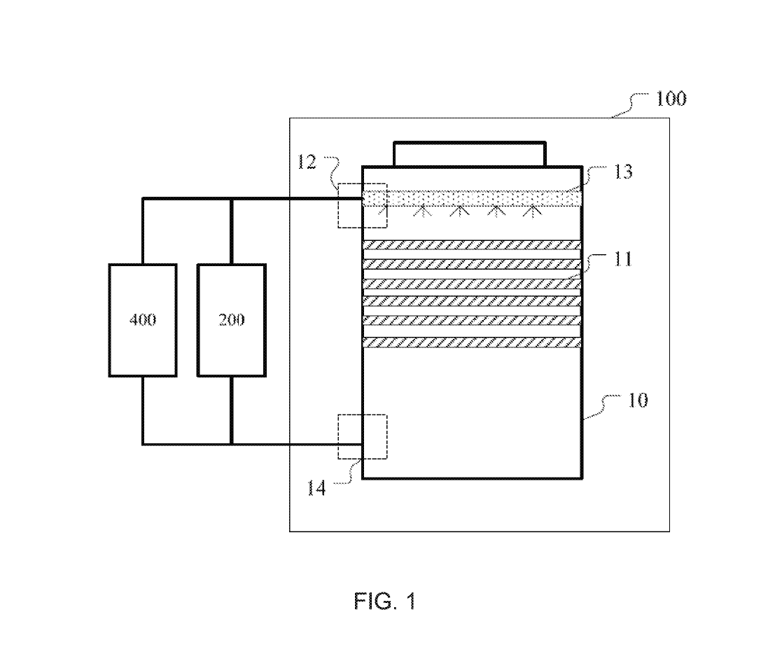

FIG. 1 shows a schematic diagram of a PCM cooling device according to one example. As shown in FIG. 1, the PCM cooling device is generally labeled as cooling device 100, and may be connected to a free cooling device 200 or a system to be cooled 400 via working fluid passages. The free cooling device 200 may be a free cooling device which performs indirect cooling. The system to be cooled 400 may be a data center, or any other system that may be cooled by using working fluid. Typically, the above mentioned working fluid is water. However, other appropriate fluid may also be employed as the working fluid. The PCM cooling device 100 may comprise a cooling tank 10, in which, a tube 11 filled with phase change material PCM and a distribution system 13 for distributing the working fluid to the tube 11, are installed. The PCM cooling device 100 further comprises an inlet module 12 and an outlet module 14, wherein the inlet module 12 introduces the working fluid from the free cooling device in a first working mode, and introduces the working fluid from the system to be cooled in a second working mode; the outlet module 14 discharges the working fluid having contacted with the tube 11 into the free cooling device in the first working mode, and discharges the working fluid having contacted with the tube 11 into the system to be cooled in the second working mode. By switching between the first working mode and the second working mode, different working fluid is allowed to contact the tube 11, such that the PCM material in the tube 11 may store and release the cold energy. The characteristics and implementing modes of the above mentioned components will be described one by one.

In the embodiments of the invention, the tube 11 is used to contain and be filled with the phase change material (PCM). As known by those skilled in the art, the phase change material (PCM) is a substance with high latent heat of phase change. In particular, when the PCM material changes from solid to liquid (i.e., when melting) it will absorb large amounts of heat; while when it changes from liquid to solid (i.e., when solidifying) it will release large amounts of heat. Although a large number of materials can change phases and have corresponding phase change latent heat, in practice, however, many materials can hardly be used as heat storage media because the melting point is not in the operating range, or the latent heat is not high enough. Therefore, the PCM material should be selected according to the requirement of actual applications, for use in the storage and releasing of heat.

When used in the application environment of cooling devices, the PCM material is required to have the following properties. First, the PCM material is required to have suitable thermal properties, comprising suitable phase-change temperature, high latent heat of phase change and good heat conductivity. In particular, the PCM material is required to have a suitable phase-change temperature (e.g., a melting point) that is matched with the working temperature of the cooling device. In addition, it is desired that the latent heat of phase change can be as high as possible in order to reduce the amount of material required in heat storage. Furthermore, good thermal conductivity would help enhancing the efficiency of energy storage and releasing.

In addition, the PCM material is required to have suitable physical properties, comprising favorable phase equilibrium, high density, small volume change and low vapor pressure. Favorable phase equilibrium refers to high phase stability of the material during the process of melting and solidification, which would help in the predicting and setting of heat storage. High density is desirable to allow a smaller size of container to contain the PCM material. Small volume changes during phase change and small vapor pressure at operating temperatures would be helpful in reducing the problem in hermetically accommodating the material.

Furthermore, it is desirable that the PCM material has suitable kinetic properties, comprising no supercooling, sufficient crystallization rate, and so on. Supercooling has been a troublesome aspect of PCM development. Supercooling of more than a few degrees will interfere obviously with proper heat extraction, and 5-10° C. supercooling can prevent heat storage and extraction entirely. Therefore, it is desirable that the PCM material has no supercooling. Sufficient crystallization rate is favorable to the storage and releasing of heat energy.

In addition, it is desirable that the PCM material has suitable chemical properties, comprising long-term chemical stability, compatibility with materials of device construction, no toxicity, and no fire hazard. Naturally, from the economic aspect, it is also desirable that the PCM material is cost effective and abundant.

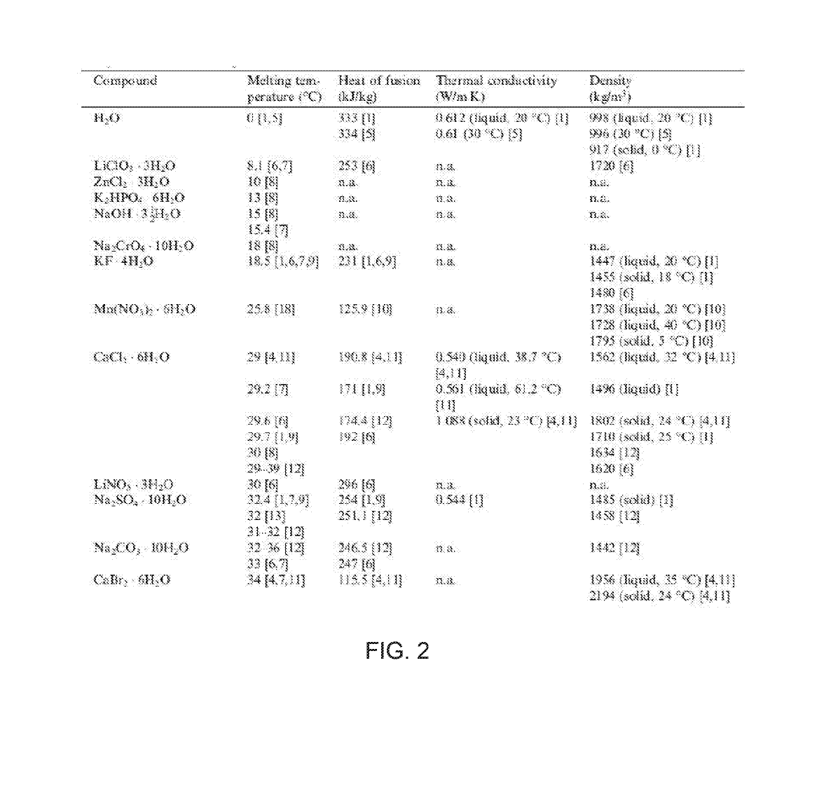

By investigating the properties of many materials, it has been found that inorganic compounds have almost double volumetric latent heat storage capacity (250-400 kg/dm³) than the organic compounds (128-200 kg/dm³), and thus are more suitable for use as the PCM materials of cooling devices. FIG. 2 shows properties of some candidate inorganic compounds, comprising melting points, latent heat, thermal conductivity and density. By synthetically considering the requirements to the PCM materials as described above, it is possible to select one or more materials from the compounds shown in FIG. 2 for use in the PCM cooling device.

On the basis of selecting suitable PCM material, the PCM material may be used to fill the tube 11 shown in FIG. 1 as an energy storage module. In order to avoid interfering with heat exchange of the PCM material, the tube 11 is formed by using material with high heat conductivity. In addition, it is desirable that the tube 11 has high rigidity to support the PCM material. In order to meet the requirements of heat conductivity and rigidity, it is necessary to properly select the material of the tube, and properly define its size. In one embodiment, metal material is used to form the tube 11. More particularly, in one example, copper is used to form the tube 11. In one example, the thickness of the tube 11 is defined as 1.5-2.5 mm, so as to give consideration to the requirements of both heat conductivity and rigidity. Besides, the diameter of the tube is properly defined. It can be understood that, if the tube has a diameter of too small, it is difficult to be filled with the PCM material; if the tube has a diameter of too large, the heat conductive capacity will be affected. Thus, in one example, the diameter of the tube is defined as 20-50 mm. Furthermore, by considering the volumetric change of the PCM material during the process of phase change and the transformation of the tube 11 per se at different temperatures, only a part of the volume, such as 70-80% of the volume, of the tube 11 is filled with the PCM material. After filled with the PCM material, the tube has its two ends sealed, for example, by way of weld.

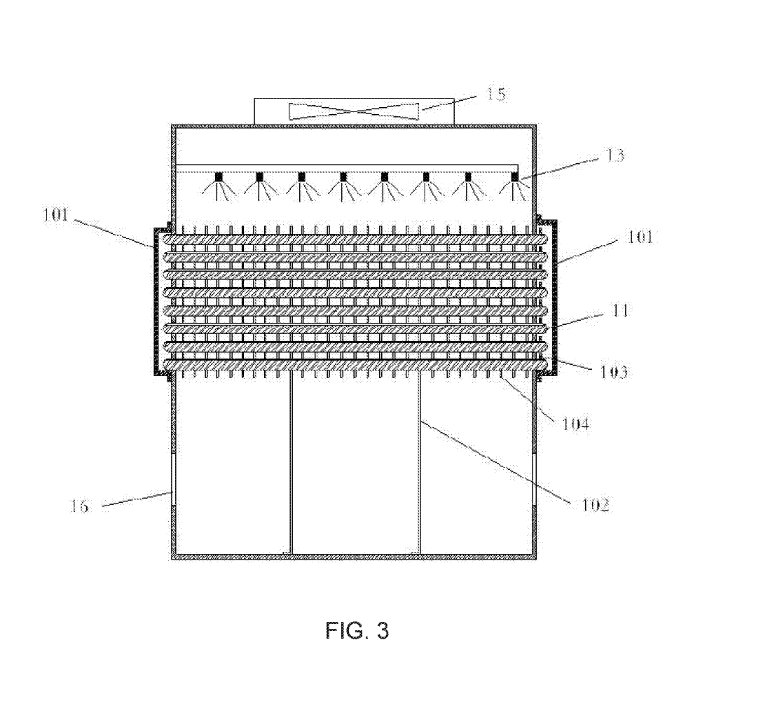

In different examples, the tube 11 may be embodied as tubes of different numbers and different shapes. For example, the tube 11 may consist of a single tube, or comprise a plurality of tubes. FIG. 3 shows a schematic diagram of the inner structure of the cooling tank according to one example. In the example shown in FIG. 3, the tube 11 is a plurality of linear tubes arranged in parallel. However, it can be understood that the tube may be of curving shape, such as spiral, winding S-shape, and so on. In the case of using more than one tube, each tube may have the same or different shapes or sizes.

In one embodiment, the tube 11 is equipped with several temperature sensors Sₚ to provide temperature feedback. In one example, the temperature sensors Sₚ are attached to the surface of the tube 11, and measure the surface temperature of the tube 11 as the temperature of the PCM material therein approximately. In another example, the temperature sensors may extend into the interior of the tube 11 to contact with the PCM material, thus measuring the temperature of the PCM material directly. The number and position of the temperature sensors may be arranged as needed.

In one example, as shown in FIG. 3, an emergency valve 103 may be installed on one end of the tube for releasing gas in the tube during maintenance.

The tube 11 may be supported by many ways. In one embodiment, the tube 11 is supported by sidewalls of the cooling tank 10. In particular, in one example, the ends of the tube 11 are directly fixed on the sidewalls of the cooling tank 10, for example, by the linking way of weld, bonding, and so on. In another example, a support portion, such as a bracket, is formed on the sidewalls of the cooling tank 11 to support the ends of the tube. In the example of FIG. 3, holes are formed on the opposite sidewalls of the cooling tank 10 to support the tube 11. In this case, the two ends of the tube will extend and be exposed outside the cooling tank 10. Thus, on the outside of the perforated sidewalls of the cooling tank 10, protection covers 101 are used to cover the ends of the tube extending out of the cooling tank, so as to prevent the tube and the working fluid therein from being exposed to outside air. A sealing ring may be used between the protection cover 101 and the sidewall of the cooling tank to isolate outside air more effectively. Thus, when a tube has a problem or needs to be replaced, what is needed is only to open the protection cover 101, and then conduct maintaining operation on the tube.

In one embodiment, support ribs are formed to support the tube 11. For example, as shown in FIG. 3, the support ribs 102 are formed on the bottom of the cooling tank 10, therefore supporting the tube 11 from below. The support ribs 102 may be formed by metal plates or metal columns, and be fixed on the bottom of the cooling tank 10 by the way of weld, bolt, etc., thus providing the tube 11 with adequate supporting force.

Additionally, the tube 11 may be supported by other ways. In one embodiment, two or more supporting ways are used in combination, for example, on the basis of supporting the tube 11 using the sidewalls of the cooling tank, the support ribs are used to provide further support, thereby enhancing the supporting strength and preventing the tube 11 from deformation.

In one embodiment, an air inlet module 16 is arranged on the wall of the cooling tank, for introducing the outside air into the cooling tank in the first working mode. In one example, a fan 15 is further arranged in the PCM cooling device, for facilitating the air inlet module 16 to introduce the outside air in the first working mode. In the example of FIG. 3, the fan 15 is arranged at the top of the cooling tank 10, and the air inlet module 16 is arranged at the bottom of the cooling tank 10. Thus, in the case that the fan 15 is working, the outside air enters into the cooling tank 10 through the air inlet module 16 at the bottom, and after contacting with the tube 11, is discharged through the fan 15 at the top, such that air flow is formed in the entire cooling tank 10. In the case that support ribs in the form of, for example, metal plates are arranged in the cooling tank 10, through-holes are arranged in the support ribs to facilitate air to flow in the cooling tank 10. Generally, the fan 15 and the air inlet module 16 work only in the first working mode. As will be described in detail below, the first working mode is applicable in the case of low ambient temperature. In this case, by opening the air inlet module 16 and preferably starting the fan 15, the outside cold air is directly introduced for heat exchange with the tube 11, thus providing the PCM material with additional cold energy.

On the other hand, in order to allow the PCM material in the tube 11 to be able to store and release energy, the tube 11 needs to have effective heat exchange with the working fluid. To this end, a distribution system 13 is further arranged in the cooling tank 10, for distributing the working fluid introduced from the inlet module 12 and allowing it to contact with the tube 11. In one example, the distribution system 13 comprises some slender fluid pipes filled with working fluid, which pipes contact directly with the tube 11, such as by twining on the surface of the tube 11, thus allowing the working fluid to have heat exchange with the PCM material in the tube 11. In the example shown in FIG. 3, the distribution system 13 comprises nozzles for directly spraying the working fluid onto the surface of the tube 11 for thermocontact. In other examples, the distribution system 13 may also be embodied as many other forms, as long as it is able to distribute the working fluid onto the tube 11 for thermocontact.

In one example, in order to enhance heat exchange between the working fluid and the tube 11, heat sinks are arranged between the tubes 11 to increase the area of thermocontact.

By the above arrangement, the tube 11 may have sufficient heat exchange with the working fluid. By switching among different working fluid, the above heat exchange process may be switched between heat absorption and heat release, thereby realizing the energy storage and release by the PCM material. For the PCM cooling device 100 shown in FIG. 1, on different temperature conditions, it is possible to select one from the free cooling device 200 and the system to be cooled 400, and introduce the corresponding working fluid into the cooling tank to have thermocontact with PCM. In one example, the above selection and switching of the working fluid are realized at least partly by an inlet module 12 and an outlet module 14.

Particularly, the inlet module 12 introduces the working fluid from the free cooling device in the first working mode, and introduces the working fluid from the system to be cooled in the second working mode. In order to introduce different working fluid, in one example, the inlet module 12 comprises a first fluid inlet and a second fluid inlet, which are connected to the free cooling device 200 and the system to be cooled 400, respectively; in addition, the first fluid inlet is arranged as opening in the first working mode and closing in the second working mode, while the second fluid inlet is arranged as closing in the first working mode and opening in the second working mode. Thus, in the first working mode, the working fluid passage corresponding to the first fluid inlet is turned on, and the working fluid from the free cooling device 200 is introduced into the cooling tank through the first fluid inlet; in the second working mode, the working fluid passage corresponding to the second fluid inlet is turned on, and the working fluid from the system to be cooled 400 is introduced into the cooling tank through the second fluid inlet. In one example, the opening and closing of the fluid inlets may be controlled by an inlet control component. The inlet control component comprises all kinds of mechanical or automatic control components, such as mechanical valves, electronically controlled valves, and so on.

After the working fluid is introduced into the cooling tank through the inlet module 12, as described above, it is distributed by the distribution system 13, and has heat exchange with the PCM material in the tube 11. The working fluid after having heat exchange is then discharged out of the cooling tank through the outlet module 14. In particular, the outlet module 14 discharges the working fluid having contacted with the tube into the free cooling device 200 in the first working mode, and discharges the working fluid having contacted with the tube into the system to be cooled 400 in the second working mode. It can be seen that, the working pattern of the outlet module 14 corresponds to that of the inlet module 12, and therefore, the outlet module 14 may be realized by using structures and components corresponding to the inlet module 12.

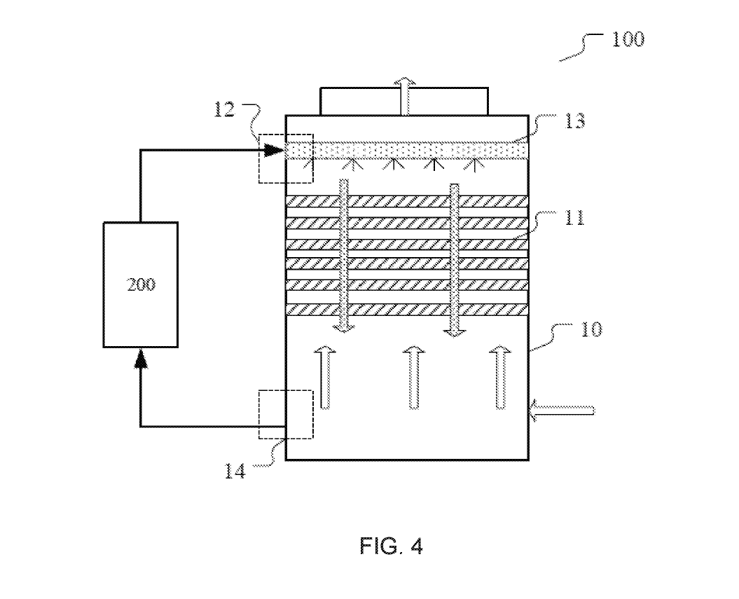

Through the selection and control by the inlet module 12 and the outlet module 14, the cooling device 100 may be switched between the first working mode and the second working mode, thus realizing energy storage and release. FIG. 4 shows a schematic diagram of the PCM cooling device functioning in the first working mode. It can be understood that, the first working mode corresponds to the process of storing cold energy, and can be applied to the following conditions: the PCM material in the cooling device 100 is in liquid state of high temperature and needs to receive cold energy; while the free cooling device 200 is in low ambient temperature, and thus may function normally to provide cooled low-temperature working fluid. At this time, as shown in FIG. 4, in this first working mode, the free cooling device 200 is connected to the cooling device 100. In particular, the low-temperature working fluid provided by the free cooling device 200 is introduced into the cooling tank through the inlet module 12, and has heat exchange with the high-temperature liquid-state PCM material in the tube 11 by the distribution system 13. Through this heat exchange, the PCM material releases heat, absorbs cold energy, thus becomes lower in temperature and solidifies gradually from liquid state to solid state. On the other hand, the working fluid absorbs heat and gets its temperature rising. The working fluid with raised temperature returns back to the free cooling device 200 through the outlet module 14, and is cooled and gets its temperature decreased once again in the free cooling device 200. During this process, the cooling device 100, by the PCM material, absorbs and stores cold energy from the free cooling device. In the case that the cooling device 100 is equipped with an air inlet and preferably a fan, in the first working mode, the air inlet is opened and the fan is turned on to introduce outside air in low temperature. On the one hand, the introduction and flow of the outside air allow the tube 11 to have more effective heat exchange with the low-temperature working fluid; on the other hand, as described above, the low temperature of the air itself may provide extra cold energy and help the cooling of the PCM material. In FIG. 4, the hollow arrows stand for the directions of air flow, and the solid arrows stand for the directions of working fluid. Under the combined effect of the low-temperature working fluid and the low-temperature flowing air, the PCM material may be cooled near the wet bulb temperature. For example, in the case that the outside dry bulb temperature is 20° C., the wet bulb temperature is 15.2° C. Thus, the PCM material may be cooled more effectively.

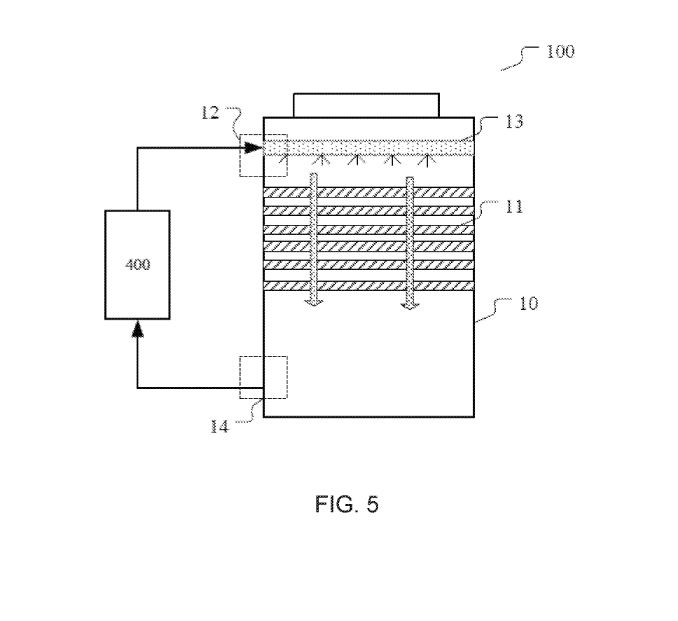

FIG. 5 shows a schematic diagram of the cooling device functioning in the second working mode. It can be understood that, the second working mode corresponds to the process of releasing cold energy, and can be applied to the following conditions: the PCM material in the cooling device 100 is in solid state of low temperature and has stored cold energy, thus being capable of cooling other systems. At this time, as shown in FIG. 5, in this second working mode, the system to be cooled 400 is connected to the cooling device 100. In particular, the high-temperature working fluid to be cooled in the system 400 is introduced into the cooling tank through the inlet module 12, and has heat exchange with the low-temperature solid-state PCM material in the tube 11 by the distribution system 13. Through this heat exchange, the PCM material absorbs heat, releases cold energy, thus becomes higher in temperature and melts gradually from solid state to liquid state. On the other hand, the working fluid releases heat and gets its temperature decreased. Thus, the working fluid with lowered temperature returns back to the system to be cooled 400 through the outlet module 14, and thus the system to be cooled 400 is cooled and gets its temperature decreased. During this process, the cooling device 100, by the PCM material, releases the stored cold energy, which is used to cool the system to be cooled 400 via the working fluid. The second working mode is generally suitable to the condition that the free cooling system is unusable due to high outside air temperature. Thus, in this working mode, the fan is turned off and the air inlet is closed, such that the cold energy stored in the PCM material can be focused to cool the working fluid.

The above described is the structure and the working process of the PCM cooling device 100, which receives and stores cold energy from the free cooling device 200, and when needed, releases the cold energy to the system to be cooled 400. Thus, the PCM cooling device 100 may be used in combination with the free cooling device 200 as a cooling system, jointly used for cooling the system to be cooled 400.

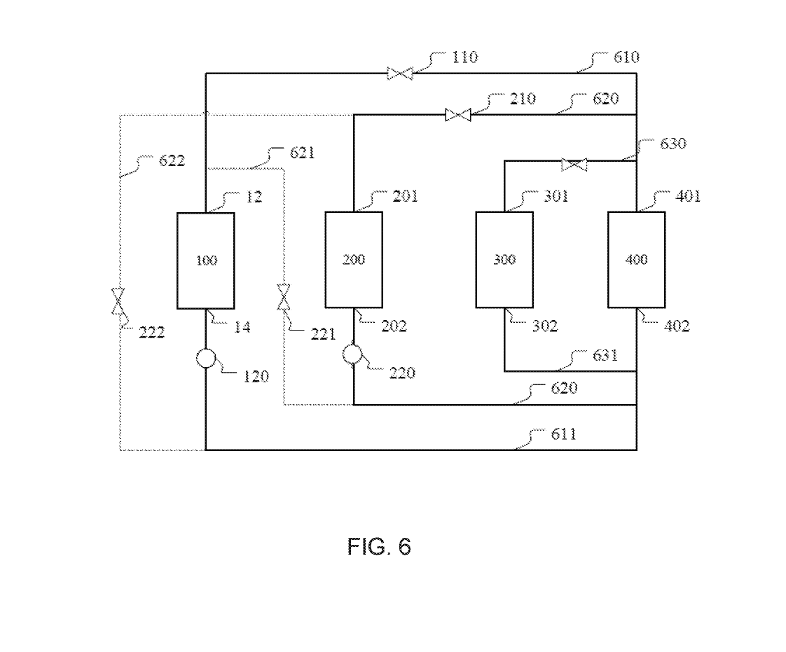

Correspondingly, according to one embodiment, the invention further provides a cooling system in which a PCM cooling device and a free cooling device are combined. FIG. 6 shows a schematic diagram of a cooling system according to one example. As shown in FIG. 6, the cooling system is generally labeled as 600, comprising a PCM cooling device 100 and a free cooling device 200, wherein the PCM cooling device 100 has the structure, material and working process as described above by referring to FIGS. 1-5, and the free cooling device 200 is an indirect cooling device that provides cooled working fluid under suitable temperature conditions. The system 600 further comprises a plurality of working fluid passages that realize fluid connection among the PCM cooling device 100, the free cooling device 200 and the system to be cooled 400. The above working fluid passages comprise the working fluid passages that connect in parallel the free cooling device 200 and the PCM cooling device 100 with the system to be cooled 400. In particular, the inlet module 12 of the PCM cooling device 100 and the fluid inlet 201 of the free cooling device 200 are connected to the fluid outlet 401 of the system to be cooled 400 via the working fluid passages 610 and 620, respectively, and the outlet module 14 of the PCM cooling device 100 and the fluid outlet 202 of the free cooling device 200 are connected to the fluid inlet 402 of the system to be cooled 400 via the working fluid passages 611 and 621, respectively. In addition, the working fluid passages further comprise, the working fluid passage that connects the fluid outlet of the free cooling device 200 with the inlet module 12 of the PCM cooling device 100, and the working fluid passage that connects the fluid inlet of the free cooling device 200 with the outlet module 14 of the PCM cooling device 100. In particular, the fluid outlet 202 of the free cooling device 200 is connected to the inlet module 12 of the PCM cooling device 100 via the working fluid passage 621, and the fluid inlet 201 of the free cooling device is connected to the outlet module 14 of the PCM cooling device via the working fluid passage 622. That is, the PCM cooling device 100 and the free cooling device 200, besides in parallel connecting to the system to be cooled 400, further “cascade” together head to tail between each other.

For the plurality of the working fluid passages, the system 600 is further equipped with passage control components for controlling the turn-on and turnoff of the plurality of the working fluid passages. In one example, the passage control components comprise a plurality of valves arranged in the working fluid passages. For example, as shown in FIG. 6, the passage control components comprise valves 110, 220, 221, 222 provided in the working fluid passages 610, 620, 621, 622, respectively, for controlling the turn-on and turnoff of the corresponding fluid passages. In one example, the passage control components further comprise flow control system provided in the working fluid passages. For example, in FIG. 6, flow control system 120 and 220 are arranged for controlling the flow rates of the working fluid flowing through the PCM cooling device 100 and the free cooling device 200, respectively. The flow control system 120 and 220 may be, for example, pumps, flow control valves, and so on. In one example, the passage control components may be mechanical components, functioning in different working modes (for example, turn-on, turnoff, or flow rate adjustment) under manual operation. In another example, the passage control components may be automatic control components, such as electromagnetic valves, which are linked to a controlling module, and in response to signals from the controlling module, turns on or off the corresponding working fluid passages.

In one example, the cooling system 600 further comprises a conventional compression-type cooling device 300, which, together with the PCM cooling device 100 and the free cooling device 200 in parallel, is connected to the system to be cooled 400. In particular, the fluid inlet 301 of the compression-type cooling device 300 is connected to the fluid outlet 401 of the system to be cooled 400 through the working fluid passage 630, and the fluid outlet 302 of the compression-type cooling device 300 is connected to the fluid inlet 402 of the system to be cooled 400 through the working fluid passage 631. Similarly, in the fluid passages relating to the compression-type cooling device 300, a valve 310 and a flow control system 320 may be arranged. The conventional compression-type cooling device 300 may provide additional cooling capacity as a complement in the case that neither the PCM cooling device 100 nor the free cooling device 200 can provide the system to be cooled 400 with required cooling strength.

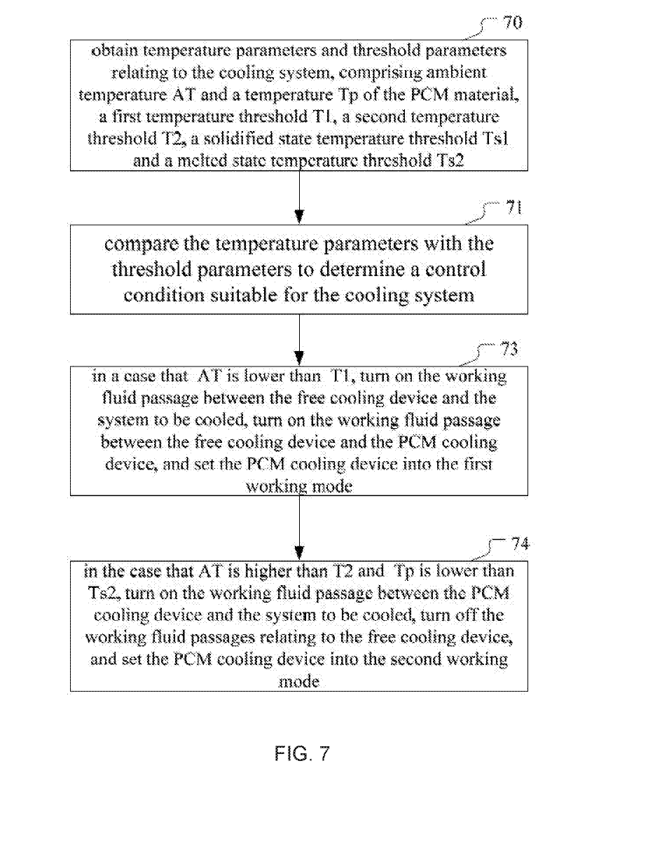

In one example, all the passage control components in the cooling system 600, comprising the valves and flow control system, are linked to and thus controlled by a controlling module 500. Correspondingly, the controlling module 500 is used for controlling the working of the cooling devices comprised in the cooling system 600. The method for controlling the cooling system 600 by the controlling module 500 will be described below. FIG. 7 shows a flow chart of a method for controlling cooling system according to one example. As shown in FIG. 7, first in step 70, the method obtains (i.e., receives) temperature parameters and threshold parameters relating to the cooling system.

The above temperature parameters comprise an ambient temperature, AT, and a temperature, Tₚ, of the PCM material in the PCM cooling device. The ambient temperature, AT, may be measured by a thermometer placed in the outside air. In one example, the outside wet bulb temperature T_{w} is employed as the above ambient temperature, AT. The temperature, Tₚ, of the PCM material may be measured by temperature sensors arranged in the PCM cooling device, such as the temperature sensor, Sₚ, arranged on the tube 11 as shown in FIG. 3.

The above threshold parameters comprise a first temperature threshold, T₁, a second temperature threshold, T₂, and material state temperature thresholds, Tₛ. The first temperature threshold, T₁, refers to the ambient temperature threshold required for the solidification of the PCM material in the PCM cooling device 100. That is, if the ambient temperature AT is lower than the threshold, T₁, the PCM cooling device 100 may store cold energy from outside and make the PCM material solidify into solid state. The first temperature threshold, T₁, depends on the employed PCM material and the efficiency of the PCM cooling device. The threshold may be predetermined by tentatively measuring the constructed PCM cooling device 100. Generally, The first temperature threshold, T₁, is lower than the melting point, Tₘ, of the PCM material, and thus may also be expressed as T₁=Tₘ−ΔT₁. The smaller ΔT₁ is, the more effective the PCM cooling device 100 is.

The second temperature threshold, T₂, refers to the ambient temperature threshold required for the proper functioning of the free cooling device 200. That, if the ambient temperature, AT, is lower than the threshold, T₂, the free cooling device may be used to cool the system to be cooled 400. The second temperature threshold, T₂, depends on some factors such as the set cooling temperature, Tₛₑₜ, of the system to be cooled 400, the cooling efficiency of the free cooling device 200, and so on. T₂ may be predetermined by tentatively measuring the free cooling device 200. Generally, the second temperature threshold, T₂, is lower than the set cooling temperature, Tₛₑₜ, and thus may also be expressed as T₂=Tₛₑₜ−ΔT₂. The smaller ΔT₂ is, the more effective the free cooling device 200 is. In addition, generally, the second temperature threshold, T₂, is higher than the first temperature threshold T₁.

The material state temperature threshold, Tₛ, are temperature thresholds measuring the state of the PCM material, comprising a solidified state temperature threshold, Tₛ₁, and a melted state temperature threshold, Tₛ₂. If the temperature, Tₚ, of the PCM material is lower than the solidified state temperature threshold, Tₛ₁, it can be indicated that the PCM material has solidified completely into solid state; if the temperature, Tₚ, of the PCM material is higher than the melted state temperature threshold Tₛ₂, it can be indicated that the PCM material has melted completely into liquid state; if the temperature, Tₚ, is between Tₛ₁ and Tₛ₂, it can be indicated that the PCM material is partly in liquid state and partly in solid state. The solidified state temperature threshold, Tₛ₁, and the melted state temperature threshold, Tₛ₂, depend on the PCM material per se, and may be predetermined by temperature measurement during the melting and solidifying process of the PCM material. Generally, Tₛ₁<Tₘ<Tₛ₂, wherein Tm is the melting point of the PCM material.

On the basis of receiving the above temperature parameters and threshold parameters, in step 71, the method compares the temperature parameters with the threshold parameters to determine the control condition. In step 73, in the case that the ambient temperature, AT, is lower than the first temperature threshold, T₁, the method turns on the working fluid passage between the free cooling device 200 and the system to be cooled 400, turns on the working fluid passage between the free cooling device 200 and the PCM cooling device 100, and sets the PCM cooling device 100 into the first working mode. Step 73 may be realized by turning on the valves 210, 221 and 222 shown in FIG. 6, turning off the valve 110, and setting the inlet module of the PCM cooling device. In one example, setting the PCM cooling device 100 into the first working mode further comprises turning on the fan and opening the air inlet in the PCM cooling device 100. By implementing step 73, the free cooling device 200 receives the working fluid in high temperature discharged from the system to be cooled 400 through the fluid passage 620, and after cooling the working fluid using the outside low temperature, returns the cooled low-temperature working fluid into the system to be cooled 400 through the fluid passage 620. In the meantime, the low-temperature working fluid discharged from the free cooling device 200 is sent to the PCM cooling device 100 through the fluid passage 621. When the PCM cooling device 100 works in the first working mode, it not only receives cold energy directly from the outside low-temperature air, but also receives from the free cooling device the low-temperature working fluid for storing cold energy, and returns the output working fluid into the free cooling device 200. In step 73, the free cooling device 200 is used not only to cool the system to be cooled 400, but also to provide the PCM cooling device with cold energy.

In one example, during the process of implementing step 73, the change of the temperature, Tₚ, of the PCM material in the PCM cooling device is monitored. In the case that the temperature, Tₚ, is lower than the solidified state temperature threshold, Tₛ₁, the operation of storing cold energy by the PCM cooling device 100 is stopped. This process may comprise, turning off the working fluid passage between the free cooling device 200 and the PCM cooling device 100, and turning off the fan and closing the air inlet in the PCM cooling device 100.

On the other hand, in step 74, in the case that the ambient temperature AT is higher than the second temperature threshold, T₂, and the temperature, Tₚ, of the PCM material in the PCM cooling device is lower than the melted state temperature threshold, Tₛ₂, the method turns on the working fluid passage between the PCM cooling device 100 and the system to be cooled 400, turns off the working fluid passages relating to the free cooling device 200, and sets the PCM cooling device 100 into the second working mode. It can be understood that, as the ambient temperature, AT, is higher than the second temperature threshold, T₂ (therefore is also higher than the first temperature threshold T₁), the free cooling device 200 can be used neither to cool the system to be cooled, nor to provide the PCM cooling device with cold energy. Thus, all the working fluid passages relating to the free cooling device 200 are turned off. On the other hand, as Tₚ is lower than the melted state temperature threshold, Tₛ₂, it is indicated that the PCM material in the PCM cooling device 100 is at least partly in solid state, and has cold energy storage. Therefore, the PCM cooling device 100 can be used to cool the system to be cooled 400. Step 74 may be realized by turning on the valve 110 in FIG. 6, turning off the valves 210, 221 and 222, and sets the inlet module of the PCM cooling device. At this time, the PCM cooling device 100 receives the working fluid in high temperature discharged from the system to be cooled 400 through the fluid passage 610, and after cooling the working fluid using the cold energy stored in the PCM material, returns the cooled low-temperature working fluid into the system to be cooled 400 through the fluid passage 611.

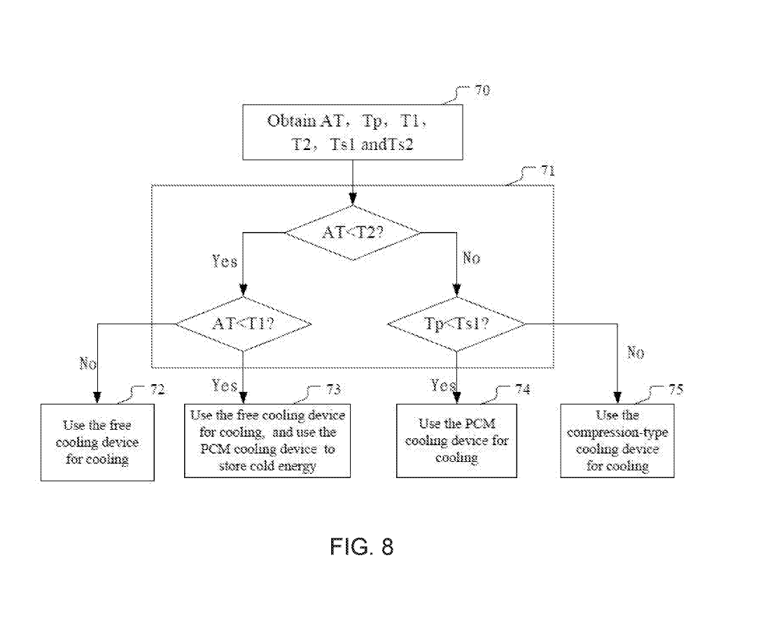

FIG. 8 shows a flow chart of a method for controlling the cooling system according to another example. The method shown in FIG. 8, besides comprising steps 73 and 74 as shown in FIG. 7, shows in more detail the comparison of the parameters in step 71; and the method shown in FIG. 8 further comprises steps under other conditions. In particular, the controlling method according to the example of FIG. 8 further comprises step 72 of, in the case that the ambient temperature, AT, is higher than the first temperature threshold, T₁, and lower than the second temperature threshold, T₂, turning on the working fluid passage between the free cooling device 200 and the system to be cooled 400, and turning off the working fluid passages relating to the PCM cooling device 100. It can be understood that, as the ambient temperature, AT, is lower than the second temperature threshold, T₂, and higher than the first temperature threshold, T₁, the free cooling device 200 may be used to cool the system to be cooled, but cannot be used to provide the PCM cooling device with cold energy. Therefore, the operation is to turn on the working fluid passage between the free cooling device 200 and the system to be cooled 400, and turn off the working fluid passages relating to the PCM cooling device 100. Step 72 may be realized by turning on the valve 210 in FIG. 6, turning off the valves 110, 221 and 222. At this time, the free cooling device 200, together with the system to be cooled 400, forms a working fluid loop through the fluid passage 620, and carries out free cooling on the system 400.

In one example, the cooling system 600 comprises a compression-type cooling device 300. Correspondingly, the controlling method according to one example further comprises step 75 of, in the case that the ambient temperature AT is higher than the second temperature threshold, T₂, and the temperature, Tₚ, of the PCM material in the PCM cooling device is higher than the melted state temperature threshold Tₛ₂, turning on the working fluid passage between the compression-type cooling device 300 and the system to be cooled 400, and turning off the working fluid passages relating to the PCM cooling device 100 and the free cooling device 200. It can be understood that, as the ambient temperature AT>T₂>T₁, the free cooling device 200 can be used neither to cool the system to be cooled, nor to provide the PCM cooling device with cold energy. On the other hand, the temperature, Tₚ, of the PCM material in the PCM cooling device is higher than the melted state temperature threshold, Tₛ₂, which indicates that all the PCM material has melted into liquid state and has no cooling capacity any more. Therefore, in this case, the conventional compression-type cooling device 300 has to be employed to cool the system to be cooled 400.

In one example, in step 70, the method receives the actual temperature, Tᵢₙ, of the system to be cooled 400, and the actual temperature may be the fluid temperature at the fluid inlet or the temperature inside the system 400. Tᵢₙ may be receives by reading the measured values of the temperature sensors arranged at the fluid inlet or inside the system. During the process of implementing one of steps 72, 73, 74, it is possible to compare Tᵢₙ with the set cooling temperature, Tₛₑₜ, of the system to be cooled 400, so as to determine whether the current cooling efficiency is sufficient, and adjust the cooling efficiency accordingly. In one example, in the case that Tᵢₙ is lower than Tₛₑₜ, the operation is to decrease the cooling efficiency of the cooling device connected operatively to the system to be cooled 400; in the case that Tᵢₙ is higher than Tₛₑₜ, the operation is to increase the cooling efficiency of the cooling device connected operatively to the system to be cooled 400. The decreasing and increasing of the cooling efficiency may be realized by decreasing and increasing the flow rate of the working fluid in the working fluid passages connected operatively to the system to be cooled, respectively. More particularly, the flow control system 120 and 220 shown in FIG. 6 may be used to adjust the flow rate of the working fluid. In one example, during the process of implementing one of steps 72, 73, 74, if the flow rate of the working fluid has been adjusted to the maximum value, but the actual temperature Tᵢₙ is still higher than the set cooling temperature Tₛₑₜ, it is indicated that the cooling efficiency of the currently employed cooling device is inadequate to cool the system to be cooled 400 to the set temperature. At this time, the operation is to further turn on the working fluid passage between the compression-type cooling device 300 and the system to be cooled 400, such that the compression-type cooling device 300 further provides additional and supplemental cold energy.

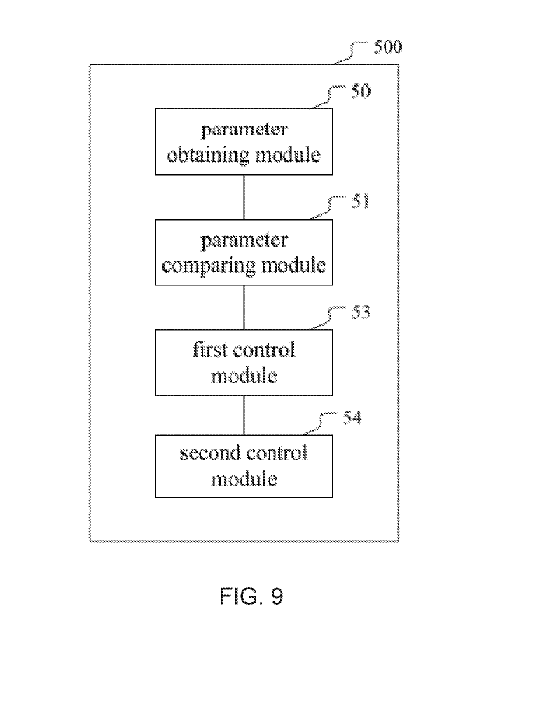

It can be understood that the above method for controlling the cooling system 600 may be carried out by the controlling module 500. FIG. 9 shows a structural block diagram of a controlling module 500 according to one example. As shown in FIG. 9, the controlling module 500 comprises a parameter obtaining module 50, a parameter comparing module 51, a first control module 53 and a second control module 54. The parameter obtaining module 50 is configured to receive temperature parameters and threshold parameters relating to the cooling system, wherein the temperature parameters comprise the ambient temperature, AT, and the temperature, Tₚ, of the PCM material in the PCM cooling device, and the threshold parameters comprise, a first temperature threshold T₁ representing the ambient temperature required for the solidification of the PCM material in the PCM cooling device, a second temperature threshold, T₂, representing the ambient temperature required for the proper functioning of the free cooling device 200, and material state temperature thresholds, Tₛ, measuring the state of the PCM material, in which the material state temperature thresholds, Tₛ, further comprise the solidified state temperature threshold, Tₛ₁, indicating that the PCM material is in solid state, and the melted state temperature threshold, Tₛ₂, indicating that the PCM material is in liquid state. The parameter comparing module 51 is configured to compare the temperature parameters with the threshold parameters to determine the control condition suitable for the cooling system.

The first control module 53 is configured to, in the case that the ambient temperature AT is lower than the first temperature threshold, T₁, turn on the working fluid passage between the free cooling device 200 and the system to be cooled 400, turn on the working fluid passage between the free cooling device 200 and the PCM cooling device 100, and set the PCM cooling device 100 into the first working mode.

The second control module 54 is configured to, in the case that the ambient temperature, AT, is higher than the second temperature threshold, T₂, and the temperature, Tₚ, of the PCM material in the PCM cooling device is lower than the melted state temperature threshold, Tₛ₂, turn on the working fluid passage between the PCM cooling device 100 and the system to be cooled 400, turn off the working fluid passages relating to the free cooling device 200, and set the PCM cooling device 100 into the second working mode.

In one example, the controlling module 500 further comprises a third controlling module (not shown), configured to, in the case that the ambient temperature, AT, is higher than the first temperature threshold, T₁, and lower than the second temperature threshold, T₂, turn on the working fluid passage between the free cooling device 200 and the system to be cooled 400, and turn off the working fluid passages relating to the PCM cooling device 100.

In one example, the cooling system 600 comprises a compression-type cooling device 300. Correspondingly, the controlling module 500 further comprises a fourth controlling module configured to, in the case that the ambient temperature, AT, is higher than the second temperature threshold, T₂, and the temperature, Tₚ, of the PCM material in the PCM cooling device is higher than the melted state temperature threshold Tₛ₂, turn on the working fluid passage between the compression-type cooling device 300 and the system to be cooled 400, turn off the working fluid passages relating to the PCM cooling device 100 and the free cooling device 200. In addition, the controlling module 500 may further comprise additional controlling modules for carrying out the operations described referring to FIGS. 7 and 8.

It can be understood that the above controlling module 500 may be realized in many ways. In one embodiment, the controlling module 500 is realized by hardware circuit. For example, the parameter obtaining module 50 may be realized as an interface circuit, directly linking to the temperature sensors and receiving their reading. The parameter comparing module 51 may comprise several comparators for comparing the temperature parameters with the corresponding thresholds and giving resulting signals. According to the resulting signals of the parameter comparing module 51, the controlling modules send control signals to passage control components in the cooling system, such as valves, flow control system, and so on, to control the turn-on or turnoff of the working fluid passages. In further one embodiment, the controlling module 500 is realized in software form. For example, software modules may be formed using computer program in order to carry out the functions of the modules in the controlling module 500. In another embodiment, the controlling module 500 may be realized in the form of combination of hardware and software, such as programmable circuit, etc.

By using the above controlling method and controlling system, the PCM cooling device and the free cooling device in the cooling system 600 are used in combination, thus storing cold energy under suitable ambient temperature. Thereby, the energy consumption can be significantly saved. Suppose the system to be cooled is a data center having an area of 100 m² and a thermal load of 80 kW, and the PCM cooling device has 10 m³ PCM material KF.4H₂O with per-module latent heat of phase change of 231 kJ/kg and density of 1450 kg/m³. Then, the total latent heat of phase change of the PCM material is 231*1450*10=3349500 kJ. Before the PCM material melts into liquid state, it will take 3349500 kJ/80 kW=11.3 hours to cool an 80 kW IT equipment using the material. Therefore, it is entirely possible to store cold energy at night by using the outside low temperature, and at day, release the cold energy to cool the data center. In addition, these operations may be applicable in many areas. Taking Paris for example, most of the time from October to May of next year, the outside air temperature is lower than 18° C. Generally, the set cooling temperature of the data center Tₛₑₜ=18° C., and therefore, at such outside temperature, it is possible to use only the free cooling device to cool. From June to September, the daytime outside temperature would be higher than 18° C., but the night temperature is still lower than 18° C., which makes it possible to store cold energy at night using PCM cooling device for further use at daytime. It can be understood that, in the case that the free cooling device is available, the energy consumption merely consists of the consumption of fans. In the case that the free cooling device and the PCM cooling device are working at the same time at night, the total energy consumption consists of the consumption of fans of the free cooling device and the consumption of PCM cooling device for storing cold energy. In the case that the PCM cooling device is employed to make cooling at daytime, the energy consumption consists of the consumption of operating the PCM cooling device. All the consumption is smaller than the energy consumption of the conventional compression-type cooling device. Taking 80 kW thermal load for example, if the outside temperature in a day is between 15-25° C., the energy consumption of cooling using compression-type cooling device is between 20-25 kw. By using the way of combining the free cooling device and the PCM cooling device, the energy consumption is estimated between 10-13 kw. As compared with the conventional cooling way, the energy consumption is decreased significantly.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A cooling device comprising:
a cooling tank with one or more sidewalls;
a tube filled with Phase Change Material (PCM) material, arranged in the cooling tank;
an inlet module, configured to introduce working fluid from a free cooling device in a first working mode, and to introduce working fluid from a system to be cooled in a second working mode;
a distribution system used to distribute the working fluid introduced from the inlet module, such that it is in contact with the tube; and
an outlet module, configured to discharge the working fluid having contacted with the tube into the free cooling device in the first working mode, and to discharge the working fluid having contacted with the tube into the system to be cooled in the second working mode.

2. The cooling device of claim 1, further comprising an air inlet arranged on one sidewall of the cooling tank, for introducing outside air into the cooling tank in the first working mode.

3. The cooling device of claim 1, wherein the cooling tank includes at least two opposing sidewalls, the cooling device further comprising:
holes formed through the opposing sidewalls to support the tube; and
protection covers are arranged on the outside of the opposing sidewalls to cover the ends of the tube extending out of the cooling tank.

4. The cooling device of claim 1, wherein the distribution system comprises at least one of:
a plurality of nozzles, for spraying the working fluid onto the surface of the tube; and
slender fluid pipes filled with working fluid, twining on the surface of the tube.

5. The cooling device of claim 1, further comprising support ribs attached to the bottom of the cooling tank for supporting the tube, wherein the support ribs have through-holes formed therein to facilitate air flow in the cooling tank.

6. The cooling device of claim 1, wherein the inlet module comprises a first fluid inlet which is connected to the free cooling device and is open in the first working mode and closed in the second working mode, and a second fluid inlet which is connected to the system to be cooled and is closed in the first working mode and open in the second working mode.

7. A cooling system comprising:
a free cooling device for providing cooled working fluid in a predetermined temperature condition;
a working fluid passage connecting the free cooling device and a PCM cooling device in parallel with a system to be cooled;
a working fluid passage connecting a fluid outlet of the free cooling device with an inlet module of the PCM cooling device;
a working fluid passage connecting a fluid inlet of the free cooling device with an outlet module of the PCM cooling device; and
passage control components for controlling a plurality of working fluid passages by turning on and turning off the plurality of working fluid passages.

8. The cooling system of claim 7, wherein the cooling system includes a compression-type cooling device, the plurality of working fluid passages further comprising:
a working fluid passage connecting the compression-type cooling device, together with the free cooling device and the PCM cooling device in parallel, to the system to be cooled.

9. A method comprising:
receiving temperature parameters and threshold parameters relating to a PCM cooling device, wherein the temperature parameters comprise ambient temperature, AT, and a temperature, Tₚ, of a PCM material in the PCM cooling device, and the threshold parameters comprise:
a first temperature threshold, T₁, representing an ambient temperature required for solidification of the PCM material in the PCM cooling device;
a second temperature threshold, T₂, representing an ambient temperature required for proper functioning of a free cooling device;
a solidified state temperature threshold, Tₛ₁, indicating that the PCM material is in a solid state; and
a melted state temperature threshold, Tₛ₂, indicating that the PCM material is in a liquid state;
comparing the temperature parameters with the threshold parameters to determine a control condition suitable for the PCM cooling device;
responsive to determining that the ambient temperature, AT, is lower than the first temperature threshold, T₁, turning on a working fluid passage between the free cooling device and the system to be cooled, turning on a working fluid passage between the free cooling device and the PCM cooling device, and setting the PCM cooling device into a first working mode; and
responsive to determining that the ambient temperature, AT, is higher than the second temperature threshold, T₂, and the temperature, Tₚ, of the PCM material is lower than the melted state temperature threshold, Tₛ₂, turning on a working fluid passage between the PCM cooling device and a system to be cooled, turning off a working fluid passages relating to the free cooling device, and setting the PCM cooling device into a second working mode.

10. The method of claim 9, wherein during setting the PCM cooling device into the first working mode, the change of the temperature, Tₚ, of the PCM material is monitored; and
responsive to determining that the temperature, Tₚ, is lower than the solidified state temperature threshold, Tₛ₁, an operation of the PCM cooling device is stopped.

11. The method of claim 9, wherein responsive to determining that the ambient temperature, AT, is higher than the first temperature threshold, T₁, and lower than the second temperature threshold, T₂, the method further comprising:
turning on the working fluid passage between the free cooling device and the system to be cooled, and turning off the working fluid passages relating to the PCM cooling device.

12. The method according to claim 9, wherein the cooling system includes a compression-type cooling device that is connected, together with the free cooling device and the PCM cooling device in parallel, to the system to be cooled, the method further comprising:
responsive to determining that the ambient temperature, AT, is higher than the second temperature threshold, T₂, and the temperature, Tₚ, of the PCM material is higher than the melted state temperature threshold, Tₛ₂, turning on a working fluid passage between the compression-type cooling device and the system to be cooled, and turning off the working fluid passages relating to the PCM cooling device and the free cooling device.

13. The method of claim 9, wherein the temperature parameters comprise an actual temperature, Tᵢₙ, of the system to be cooled, the threshold parameters comprise a set cooling temperature, Tₛₑₜ, of the system to be cooled, the method further comprising:
responsive to determining that Tᵢₙ is lower than Tₛₑₜ, decreasing cooling efficiency of the cooling device connected operatively to the system to be cooled; and
responsive to determining that Tᵢₙ is higher than Tₛₑₜ, increasing a cooling efficiency of the cooling device connected operatively to the system to be cooled.

14. The method of claim 13, wherein the cooling system includes a compression-type cooling device that is connected, together with the free cooling device and the PCM cooling device in parallel, to the system to be cooled, further comprising:
responsive to determining that the cooling efficiency of the cooling device connected operatively to the system to be cooled has been adjusted to the maximum value but Tᵢₙ is still higher than Tₛₑₜ, turning on the working fluid passage between a compression-type cooling device and the system to be cooled.

15. (canceled)
